(19) United States
(12) Patent Application Publication
(10) Pub. No.: US 2024/0145420 A1
(43) Pub. Date: May 2, 2024

(54) LIQUID METAL SHIELD FOR FINE PITCH INTERCONNECTS

(71) Applicant: Intel Corporation, Santa Clara, CA (US)

(72) Inventors: Bok Eng CHEAH, Pulau Pinang (MY); Seok Ling LIM, Kulim Kedah (MY); Kooi Chi OOI, Pulau Pinang (MY); Jackson Chung Peng KONG, Pulau Pinang (MY); Jenny Shio Yin ONG, Pulau Pinang (MY)

(21) Appl. No.: 17/975,654

(22) Filed: Oct. 28, 2022

(51) Int. Cl. H01L 23/00

(52) U.S. Cl. CPC H01L 24/26; H01L 24/14; H01L 24/16; H01L 24/27; H01L 24/29; H01L 24/30; H01L 24/73; H01L 24/81; H01L 24/83; H01L 2224/13101; H01L 2224/13105; H01L 2224/13109; H01L 2224/13111; H01L 2224/13188; H01L 2224/1413; H01L 2224/16227; H01L 2224/26175; H01L 2224/27013; H01L 2224/2732; H01L 2224/29011; H01L 2224/29013; H01L 2224/29014; H01L 2224/30051; H01L 2224/3016; H01L 2224/32227; H01L 2224/73103; H01L 2224/73204; H01L 2224/81815; H01L 2224/83007; H01L 2224/831; H01L 2224/83193; H01L 2924/01037; H01L 2924/01055; H01L 2924/01087; H01L 2924/0133; H01L 2924/0543; H01L 2924/0665; H01L 2924/07025; H01L 2924/0715; H01L 2924/1432; H01L 2924/1434

(57) ABSTRACT

The present disclosure generally relates to an electronic assembly. The electronic assembly may include a substrate including a plurality of first contact pads, a plurality of second contact pads, and a plurality of third contact pads. The electronic assembly may include a first device including a first footprint coupled to the substrate at a first surface. The electronic assembly may include a frame arranged between the first device and the substrate, the frame including a dielectric material, the frame further including a main frame extending around the first device, and further including a plurality of sub-frames encircling the plurality of first contact pads and the plurality of second contact pads on the substrate, wherein the frame may further include a conductive layer extending at least partially across the main frame.

### BACKGROUND

There are challenges in addressing signal integrity performance degradation ascribed to electromagnetic interference (EMI) and/or crosstalk coupling occurring at tightly coupled first level interconnects (FLI), i.e., interconnection between a silicon die and a package substrate with a bump pitch geometry≤110 μm. Signal margin degradation due to crosstalk noise has increasingly become a limiting factor for I/O data-rate and silicon area scaling especially for single-ended bus, e.g., modular die fabric interconnects (MDFI), package die-to-die interconnects (8 Gbps-32 Gbps) or memory interface (>8500 MT/s).

Current solutions to mitigate FLI bumpout crosstalk coupling include:
a) Reduced Signal:Ground (S:G) ratio, e.g., from 4:1 to 2:1 or 1:1 for improved EMI shielding between adjacent interconnects.
b) Implementation of a ground-webbing design (shielding signal bump pads through conductive traces associated to Vss/ground reference voltage) at package substrate.
c) Restriction of minimum C4 bump pitch geometry threshold, e.g., 110 μm to 130 μm to minimize the electromagnetic coupling between adjacent bumps.
d) Receiver (RX) device circuitry equalization or termination feature(s) for improved signal integrity performance and margins.

However, there are disadvantages associated with the above-mentioned solutions. For example, a reduction of the S:G ratio and a restriction of bump pitch geometry scaling may lead to an increased silicon footprint penalty, thereby rising silicon fabrication or manufacturing costs. Further, the implementation of a package ground-webbing design may not be able to fully resolve the EM coupling, especially at the FLI stand-off height regions, and may often be limited by routing density at confined bump break-out area. Finally, the implementation of a RX device circuitry equalization and/or termination feature(s) may lead to higher power consumption, thus hindering a power-efficient system device.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. The dimensions of the various features or elements may be arbitrarily expanded or reduced for clarity. In the following description, various aspects of the present disclosure are described with reference to the following drawings, in which:

FIG. 1A shows a cross-sectional view of an electronic assembly according to an aspect of the present disclosure;

FIG. 1B shows a top view layout of the electronic assembly according to the aspect as shown in FIG. 1A;

FIG. 2 shows a cross-sectional view of an electronic assembly according to another aspect of the present disclosure;

FIGS. 3A through 3F show cross-sectional and top views directed to an exemplary simplified process flow for forming an electronic assembly according to an aspect that is generally similar to that shown in FIG. 1A of the present disclosure;

FIG. 4 shows an illustration of a computing device that includes an electronic assembly according to a further aspect of the present disclosure; and

FIG. 5 shows a flow chart illustrating a method for forming an electronic assembly according to an aspect of the present disclosure.

### DETAILED DESCRIPTION

The following detailed description refers to the accompanying drawings that show, by way of illustration, specific details and aspects in which the present disclosure may be practiced. These aspects are described in sufficient detail to enable those skilled in the art to practice the present disclosure. Various aspects are provided for devices, and various aspects are provided for methods. It will be understood that the basic properties of the devices also hold for the methods and vice versa. Other aspects may be utilized and structural, and logical changes may be made without departing from the scope of the present disclosure. The various aspects are not necessarily mutually exclusive, as some aspects may be combined with one or more other aspects to form new aspects.

Present disclosure may attempt to address signal integrity performance degradation ascribed to electromagnetic interference (EMI) and/or crosstalk coupling occurring at tightly coupled first level interconnects (FLI), i.e., interconnection between a silicon die and a package substrate with a bump pitch geometry≤110 μm.

Technical advantages of the present disclosure may include, but not limited to:
i) Silicon footprint reduction through continuous silicon bump pitch scaling, i.e., <110 μm.
ii) Device performance (data bandwidth) improvement with higher I/O density through bump pitch reduction and/or relaxation of Signal-to-Ground ratio requirements.
iii) Improved signal integrity performance through improved vertical crosstalk shielding at the C4 interconnects; additional voltage reference or shielding for signal traces routed on package surface layer especially at bump break-out (die shadow) regions.
iv) Improved power integrity performance through improved Imax capacity at the first level interconnects through increased Vcc bump contact area and/or volume for the power delivery network (PDN).
v) Improved package warpage control through the composite of dielectric frame (e.g., mold layer) and liquid metal layer at FLI interconnect; alternative solution to package stiffener solution that requires package real-estate trade-off and restriction of die-side component placement.

The present disclosure generally relates to a device, e.g., an electronic assembly. The electronic assembly may include a substrate including a plurality of first contact pads, a plurality of second contact pads, and a plurality of third contact pads. The electronic assembly may include a first device including a first footprint coupled to the substrate at a first surface. The electronic assembly may include a frame arranged between the first device and the substrate, the frame including a dielectric material, the frame further including a main frame extending around the first device, and further including a plurality of sub-frames encircling the plurality of first contact pads and the plurality of second contact pads on the substrate, wherein the frame may further include a conductive layer extending at least partially across the main frame.

The present disclosure also generally relates to a computing device. The computing device may include a circuit board and an electronic assembly coupled to the circuit board. The electronic assembly may include a substrate including a plurality of first contact pads, a plurality of second contact pads, and a plurality of third contact pads. The electronic assembly may include a first device including a first footprint coupled to the substrate at a first surface. The electronic assembly may include a frame arranged between the first device and the substrate, the frame including a dielectric material, the frame further including a main frame extending around the first device, and further including a plurality of sub-frames encircling the plurality of first contact pads and the plurality of second contact pads on the substrate, wherein the frame may further include a conductive layer extending at least partially across the main frame.

The present disclosure further generally relates to a method. The method may include forming a plurality of first contact pads, a plurality of second contact pads, and a plurality of third contact pads on a substrate. The method may also include coupling a first device to the substrate at a first surface. The method may further include forming a main frame and a plurality of sub-frames in a frame, the frame comprising a dielectric material, extending the main frame around the first device and encircling the plurality of sub-frames around the plurality of first contact pads and the plurality of second contact pads. The method may include forming a conductive layer in the frame and extending the conductive layer at least partially across the main frame, and arranging the frame between the first device and the substrate.

To more readily understand and put into practical effect the present disclosure, particular aspects will now be described by way of examples and not limitations, and with reference to the drawings. For the sake of brevity, duplicate descriptions of features and properties may be omitted.

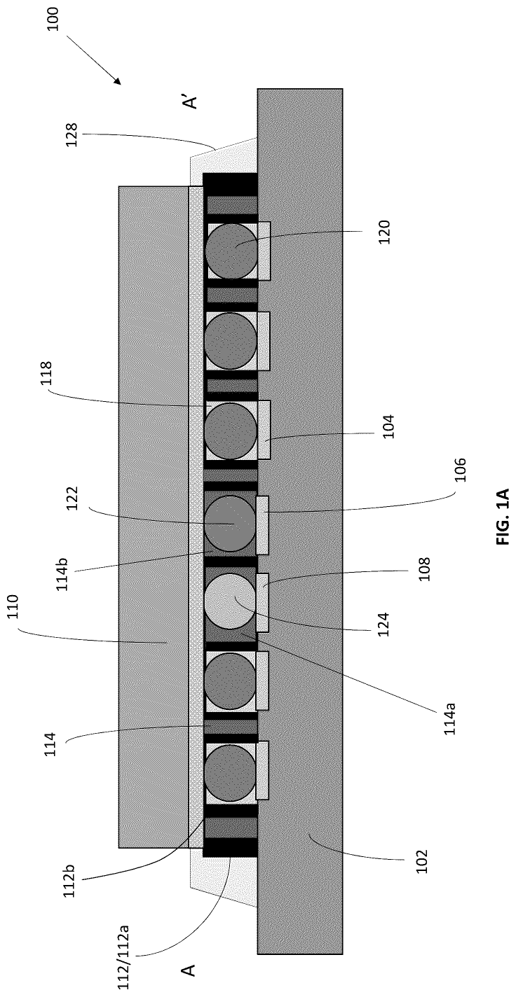

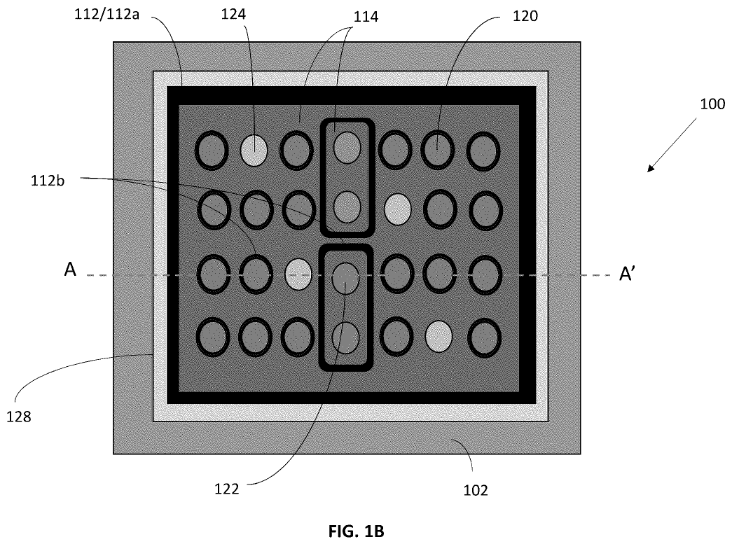

FIG. 1A shows a cross-sectional view of an electronic assembly 100 according to an aspect of the present disclosure. The electronic assembly 100 may be provided with liquid metal shield for an improved computing performance and device miniaturization. The cross-section is taken along the A-A′ line of FIG. 1B.

The electronic assembly 100 may include a package substrate, or simply termed, a substrate 102. The substrate 102 may include, for example, a silicon substrate or interposer, a multi-layer organic package, or a printed circuit board (PCB).

In various aspects, the substrate 102 may include a plurality of first contact pads 104, may also include a plurality of second contact pads 106, and may further include a plurality of third contact pads 108. The plurality of first contact pads 104, the plurality of second contact pads 106, and the plurality of third contact pads 108 may be formed on the same surface of the substrate 102 and may be located adjacent, near, or in close proximity to one another.

In the aspect shown in FIG. 1A, the plurality of second contact pads 106 may be located between the plurality of third contact pads 108 and the plurality of first contact pads 104.

The electronic assembly 100 may also include a first device 110 having a first surface and a first footprint. The first device 110 may include a central processing unit (CPU), a graphic processing unit (GPU), a system-on-chip (SOC), a memory device, a platform controller hub (PCH), a field programmable gate array (FGPA), an input/output (I/O) tile, or a combination thereof. The first device 110 may be coupled to the substrate 102, for example, at the first surface of the first device 110.

The electronic assembly 100 may further a frame 112. The frame 112 may include a dielectric material. The frame 112 may include additional materials. The frame 112 may include an organic mold compound layer, an epoxy polymer, a polyimide layer, or a silicone layer. The frame 112 may be arranged between the first device 110 and the substrate 102. In one aspect, the frame 112 may be coupled to the first device 110, and may be further coupled to the substrate 102. For example, the frame 112 may be directly coupled to the substrate 102. In various aspects, the frame 112 may include a main frame 112a and a plurality of sub-frames 112b.

In the aspect shown in FIG. 1A, the main frame 112a of the frame 112 may extend around the first device 110. In other words, the main frame 112a of the frame 112 may include a second footprint that is larger than the first footprint of the first device 110.

In the aspect shown in FIG. 1A, the plurality of sub-frames 112b may encircle or surround the plurality of first contact pads 104 and the plurality of second contact pads 106 on the substrate 102.

In various aspects, the frame 112 may further include a conductive layer 114. In one aspect, the conductive layer 114 may be present in the main frame 112a and in some but not all of the sub-frames 112b. In other words, the conductive layer 114 may extend at least partially across the main frame 112a. A first underfill layer 118 may be present in the sub-frames 112 where the conductive layer 114 may be absent.

In various aspects, the conductive layer 114 may include a liquid metal. The liquid metal may be able to fill in tiny or constrained gaps (with tighter bump spacing) given the liquidous or fluidic nature, and hence may be able to provide a continuous electrical shielding and/or current return path. The liquid metal may include a metal alloy composite. The liquid metal may be selected from the group consisting of tin, indium, gallium, francium, cesium, and rubidium. In one example, the liquid metal may be gallium-indium-tin (GaInSn) alloy or gallium oxide (Ga₂O₃).

Electrical connections, such as solder bumps, may be provided to electrically couple the first device 110 to the substrate 102. In the aspect shown in FIG. 1A, signal (I/O) bumps 120 and power (Vcc) bumps 122 may be provided in the sub-frames 112b, while ground (Vss) bumps 124 may be provided in the main frame 112a.

The signal bumps 120 may be located in the sub-frames 112b where the first underfill layer 118 may be present, and may provide an electrical coupling between the first device 110 and the plurality of first contact pads 104.

The power bumps 122 may be located in the sub-frames 112b where the conductive layer 114 may be present, and may provide an electrical coupling between the first device 110 and the plurality of second contact pads 106.

The ground bumps 124 may be located in the main frame 112a where the conductive layer 114 may be present, and may provide an electrical coupling between the first device 110 and the plurality of third contact pads 108.

The power bumps 122 and the ground bumps 124 may be arranged such that they may be adjacent to each other.

In various aspects, the electronic assembly 100 may further include a second underfill layer 128 to encapsulate the frame 112.

In various aspects, the ground bumps 124 may be coupled to the conductive layer 114 extending at least partially within the main frame 112a. In an aspect, the conductive layer 114 may be associated with a ground reference voltage (Vss) through the ground bumps 124. The conductive layer 114 associated to the ground reference voltage (Vss) may be referred to as a ground conductive layer 114a. In other words, the conductive layer 114 in main frame 112a (coupled to Vss) may not be in contact with the conductive layer 114 in the sub-frame 112b (coupled to Vcc).

In various aspects, the power bumps 122 may be coupled to the conductive layer 114 extending at least partially within a power sub-frame 112b. In an aspect, the conductive layer 114 may be associated with a power supply voltage (Vcc) through the power bumps 122. The conductive layer 114 associated to the power supply voltage (Vcc) may be referred to as a power conductive layer 114b.

FIG. 1B shows a top view layout of the electronic assembly 100 according to the aspect as shown in FIG. 1A, except that for brevity, the first device 110 is not shown.

The substrate 102 may include a footprint or perimeter. The frame 112 may include a footprint. The footprint of the frame 112 may fall within the footprint of the substrate 102.

In the aspect shown in FIG. 1B, the frame 112 may include a main frame 112a having a square or rectangular top view, and may further include a sub-frame 112b having a circular top view.

Signal (I/O) bumps 120, power (Vcc) bumps 122, and ground (Vss) bumps 124 may be arranged within the footprint of the frame 112.

The signal bumps 120 may be encircled by the sub-frames 112b and may be isolated from the conductive layer 114. In other words, in the sub-frames 112b including the signal bumps 120, the conductive layer 114 may not be present.

On the other hand, the power bumps 122 and the ground bumps 124 may be in contact with the conductive layer 114. In the aspect shown in FIG. 1B, the power bumps 122 may be located within the sub-frames 112b and may be in contact with the conductive layer 114.

The second underfill layer 128 may include a footprint and as described in earlier paragraphs, the footprint of the second underfill layer 128 may be larger than the footprint of the first device 110 (not shown).

The footprint of the layer 112 may fall within the perimeter of the second underfill layer 128, which in turn, may fall within the perimeter of the substrate 102.

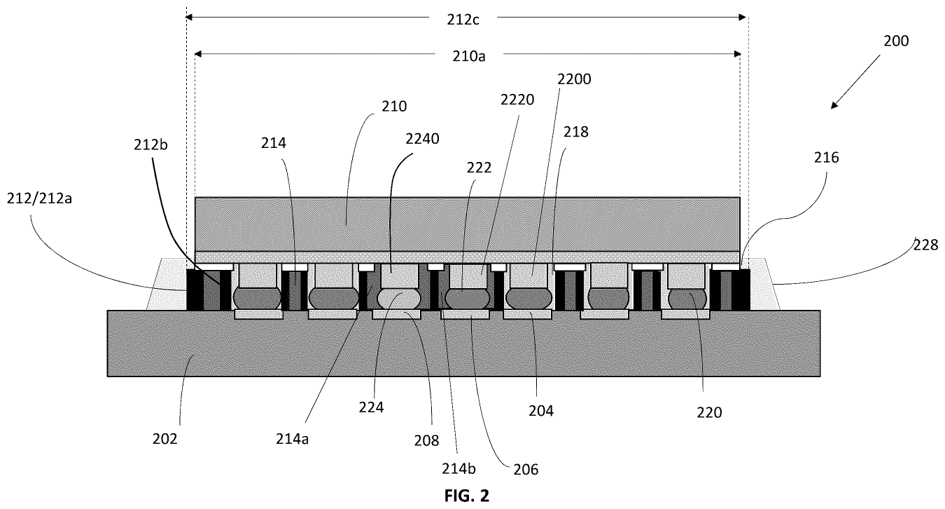

FIG. 2 shows a cross-sectional view of an electronic assembly according to another aspect of the present disclosure. The electronic assembly 200 may be similar to the electronic assembly 100 of FIG. 1A and may include additional variations and components as described below.

The electronic assembly 200 may include a package substrate, or simply termed, a substrate 202. The substrate 202 may include, for example, a silicon substrate or interposer, a multi-layer organic package, or a printed circuit board (PCB).

In various aspects, the substrate 202 may include a plurality of first contact pads 204, may also include a plurality of second contact pads 206, and may further include a plurality of third contact pads 208. The plurality of first contact pads 204, the plurality of second contact pads 206, and the plurality of third contact pads 208 may be formed on the same surface of the substrate 202 and may be located adjacent, near, or in close proximity to one another.

In the aspect shown in FIG. 2, the plurality of second contact pads 206 may be located between the plurality of third contact pads 208 and the plurality of first contact pads 204.

The electronic assembly 200 may also include a first device 210 having a first surface and a first footprint 210a. The first device 210 may include a central processing unit (CPU), a graphic processing unit (GPU), a system-on-chip (SOC), a memory device, a platform controller hub (PCH), a field programmable gate array (FGPA), an input/output (I/O) tile, or a combination thereof. The first device 210 may be coupled to the substrate 202, for example, at the first surface of the first device 210.

The electronic assembly 200 may further a frame 212. The frame 212 may include a dielectric material. The frame 212 may include additional materials. The frame 212 may include an organic mold compound layer, an epoxy polymer, a polyimide layer, or a silicone layer. The frame 212 may be arranged between the first device 210 and the substrate 202. In one aspect, the frame 212 may be coupled to the first device 210, and may be further coupled to the substrate 202. For example, the frame 212 may be directly coupled to the substrate 202. Alternatively, as shown in FIG. 2, the frame 212 may be coupled to the first surface of the first device 204 through an adhesive layer 216.

In an aspect, the frame 212 may include a first thickness ranging from 30 μm to 300 μm. In an aspect, the first thickness may correspond to a stand-off gap between the first device 210 and the substrate 202.

In various aspects, the frame 212 may include a main frame 212a and a plurality of sub-frames 212b.

In the aspect shown in FIG. 2, the main frame 212a of the frame 212 may extend around the first device 210. In other words, the main frame 212a of the frame 212 may include a second footprint 212c that is larger than the first footprint 210a of the first device 210.

In the aspect shown in FIG. 2, the plurality of sub-frames 212b may encircle or surround the plurality of first contact pads 204 and the plurality of second contact pads 206 on the substrate 202.

In various aspects, the frame 212 may further include a conductive layer 214. In one aspect, the conductive layer 214 may be present in the main frame 212a and in some but not all of the sub-frames 212b. In other words, the conductive layer 214 may extend at least partially across the main frame 212a. A first underfill layer 218 may be present in the sub-frames 212 where the conductive layer 214 may be absent.

In various aspects, the conductive layer 214 may include a liquid metal. The liquid metal may be able to fill in tiny or constrained gaps (with tighter bump spacing) given the liquidous or fluidic nature, and hence may be able to provide a continuous electrical shielding and/or current return path. The liquid metal may include a metal alloy composite. The liquid metal may be selected from the group consisting of tin, indium, gallium, francium, cesium, and rubidium. In one example, the liquid metal may be gallium-indium-tin (GaInSn) alloy or gallium oxide (Ga₂O₃).

Electrical connections may be provided to electrically couple the first device 210 to the substrate 202.

In various aspects, the first device 210 may include a plurality of interconnects, e.g., solder and/or copper column interconnects, extending from the first surface coupled to the plurality of first contact pads 204, the plurality of second contact pads 206, and the plurality of third contact pads 208.

In the aspect shown in FIG. 2, the plurality of interconnects may include a plurality of first interconnects coupled to the first contact pads 204. In one aspect, the plurality of first interconnects may include a signal (I/O) bump 220 and a copper column 2200. The first interconnects may be configured to facilitate signal transmission such as a single-ended or a differential pair signal.

The plurality of interconnects may further include a plurality of second interconnects coupled to the second contact pads 206. In one aspect, the plurality of second interconnects may include a power (Vcc) bump 222 and a copper column 2220. The second interconnects may be configured to facilitate power delivery from the substrate 202 to the first device 210.

The plurality of interconnects may also include a plurality of third interconnects coupled to the third contact pads 208. In one aspect, the plurality of third interconnects may include a ground (Vss) bump 224 and a copper column 2240. The third interconnect may be configured to a ground reference voltage to facilitate current return path.

In the aspect shown in FIG. 2, the signal bumps 220 and the power bumps 222 may be provided in the sub-frames 212b, while the ground bumps 224 may be provided in the main frame 212a.

The signal bumps 220 may be located in the sub-frames 212b where the first underfill layer 218 may be present, and may provide an electrical coupling between the first device 210 and the plurality of first contact pads 204.

The power bumps 222 may be located in the sub-frames 212b where the conductive layer 214 may be present, and may provide an electrical coupling between the first device 210 and the plurality of second contact pads 206. The sub-frames 212b including the power bumps 222 may be referred to as a power sub-frame 212b.

The ground bumps 224 may be located in the main frame 212a where the conductive layer 214 may be present, and may provide an electrical coupling between the first device 210 and the plurality of third contact pads 208.

The power bumps 222 and the ground bumps 224 may be arranged such that they may be adjacent to each other.

In various aspects, the electronic assembly 200 may further include a second underfill layer 228 to encapsulate the frame 212.

In various aspects, the plurality of third interconnects may be coupled to the conductive layer 214 extending at least partially within the main frame 212a. In an aspect, the conductive layer 214 may be associated with a ground reference voltage (Vss), through the plurality of third interconnects. The conductive layer 214 associated to the ground reference voltage (Vss) may be referred to as a ground conductive layer 214a. In other words, the conductive layer 214 in main frame 212a (coupled to Vss) may not be in contact with the conductive layer 214 in the sub-frame 212b (coupled to Vcc).

In various aspects, the plurality of second interconnects may be coupled to the conductive layer 214 extending at least partially within the power sub-frame 212b. In an aspect, the conductive layer 214 may be associated with a power supply voltage (Vcc) through the plurality of second interconnects. The conductive layer 214 associated to the power supply voltage (Vcc) may be referred to as a power conductive layer 214b.

In an aspect, the power sub-frame 212b may be configured to include two or more second interconnects to facilitate improved power delivery.

In an aspect, the two or more second interconnects may be coupled to the conductive layer 214 within the power sub-frame 212b for improved Imax capacity through reduced interconnect resistance (larger interconnect volume).

The power conductive layer with increased interconnect area/volume (compared to conventional discrete solder bump interconnects) may reduce resistance/losses, hence may improve power delivery to the first device 210.

In an aspect, the first and the second interconnects may be isolated from the ground conductive layer 214a through the sub-frames 212b.

In an aspect, the first interconnect may be isolated from an adjacent second interconnect through the sub-frames 212b and the ground conductive layer 214a.

In an aspect, a pair of first interconnects may be configured within a respective sub-frames 212b to facilitate a differential pair signal, e.g., a universal serial bus (USB) 4.0 or a peripheral component interconnect express (PCIe) Gen 6.0 or Gen 7.0 signal. In other words, for differential pair, a first signal and a complimentary second signal may not reside within the same sub-frame 212b. If the two signals reside within the same sub-frame, they may be shorted. Unlike for a power sub-frame, power bumps may be allowed to be shorted to create larger area/volume as described above.

In an aspect, the two or more second interconnects and the power conductive layer 214b within the power sub-frame 212b may be coupled to the power plane of the first device 210 at the first surface.

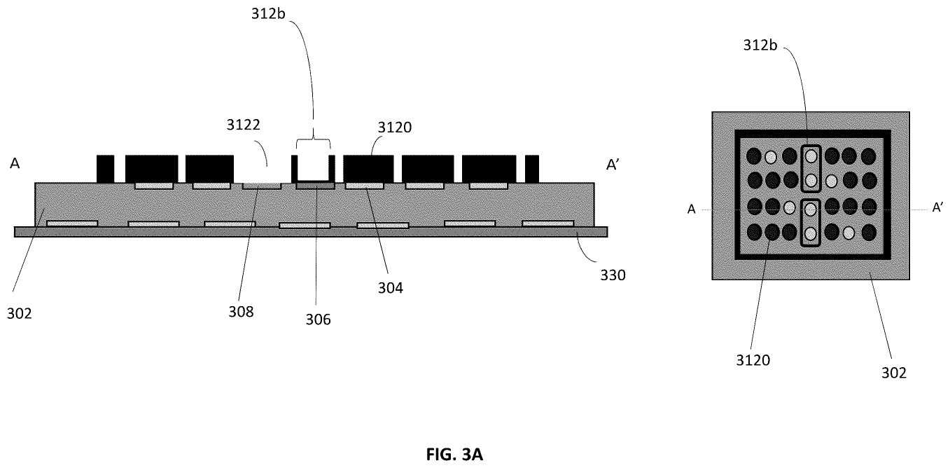

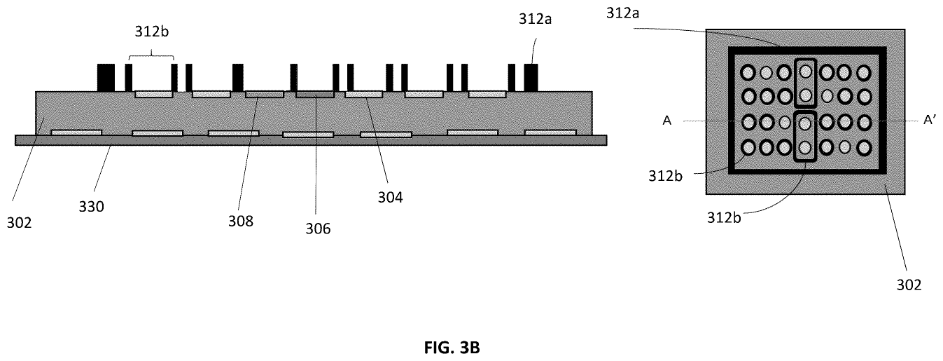

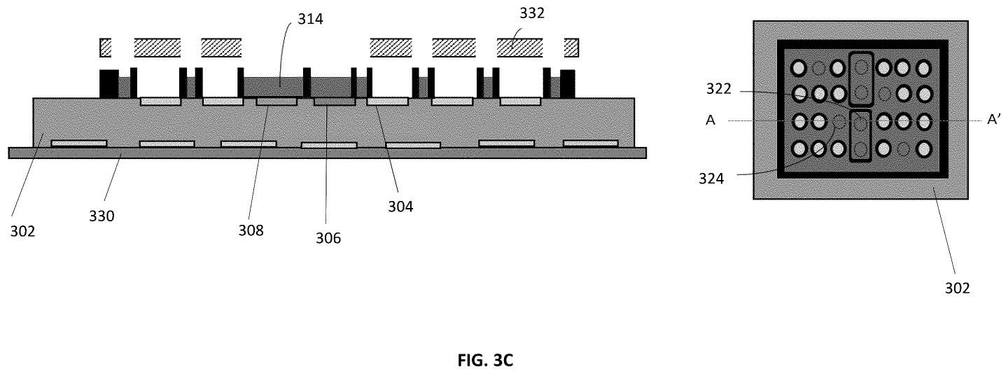

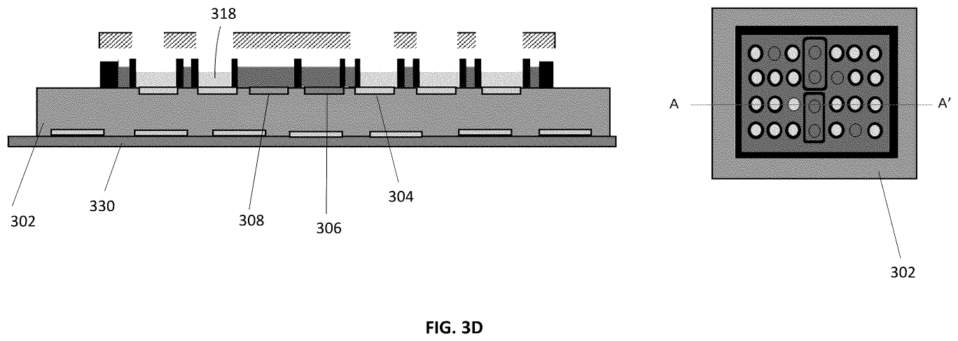

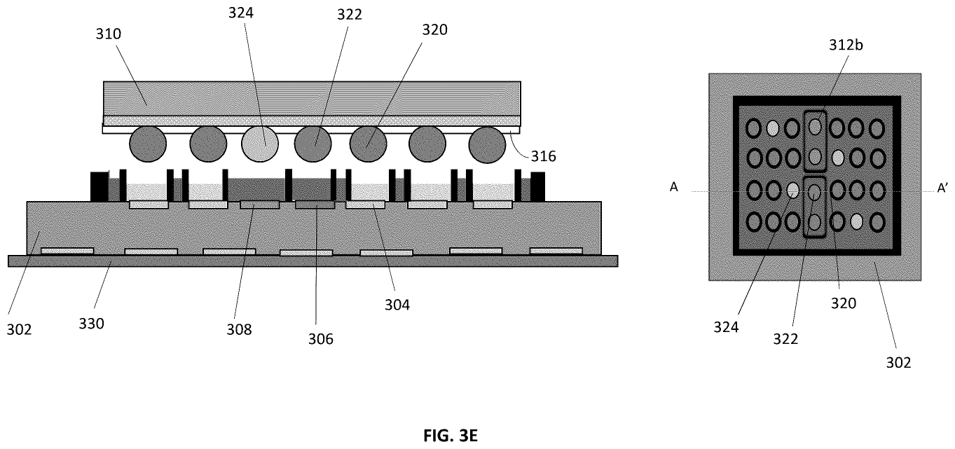

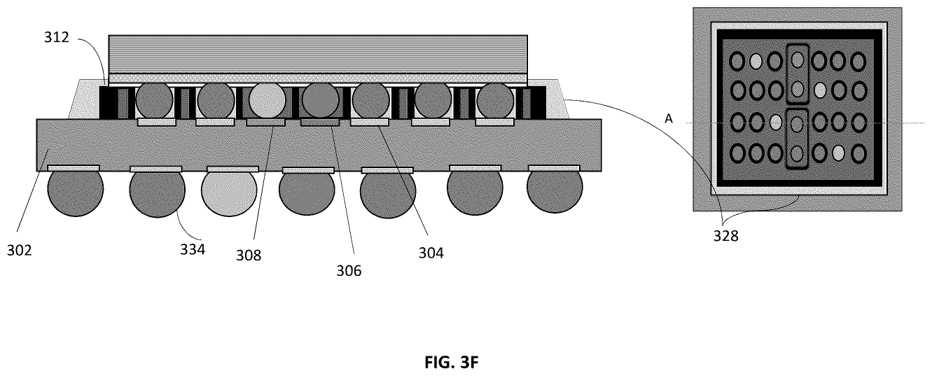

FIGS. 3A through 3F show cross-sectional and top views directed to an exemplary simplified process flow for forming an electronic assembly according to an aspect that is generally similar to that shown in FIG. 1A of the present disclosure. The cross-section view (left) is taken along the A-A′ line of the top view (right).

FIG. 3A shows formation of a dielectric layer 3120. First, a substrate 302 may be adhered onto a carrier 330. The substrate 302 may include first contact pads 304, second contact pads 306, and third contact pads 308. Next, the dielectric layer 3120 may be deposited onto the substrate 302. The dielectric layer 3120 may not be formed of a continuous layer. In other words, as shown in FIG. 3A, there may be dielectric openings or recesses 3122 present in the dielectric layer 3120. The dielectric layer 3120 may also include pre-formed sub-frames 312b. The dielectric layer 3120 may be formed such that portions of the dielectric layer 3120 may be in direct contact with the first contact pads 304. The pre-formed sub-frames 312b may be aligned and coincide with the second contact pads 306. The dielectric opening 3122 may be aligned and coincide with the third contact pads 308. Conventional techniques may be employed, such as but not limited to, compression, injection or transfer molding process. As shown in the top view, the pre-formed sub-frames 312b may be rectangular and may later encircle the second contact pads 306.

FIG. 3B shows formation of a dielectric frame 312. Portions of the dielectric layer 3120 may be removed such that a main frame 312a and a plurality of sub-frames 312b may be formed. In addition to the pre-formed sub-frames 312b that may be aligned with the second contact pads, further sub-frames 312b may be formed by conventional techniques, such as but not limited to, laser/mechanical drilling, that may be aligned with the first contact pads. The pre-formed sub-frames 312b that are aligned with the second contact pads 306 may be conveniently termed as power sub-frames 312b if the second contact pads 306 are associated with a power voltage (Vcc).

FIG. 3C shows formation of a conductive layer 314, e.g., a liquid metal, in the main frame 312a. A stencil 332 may be provided and positioned over portions of the dielectric frame 312 where the conductive layer 314 may not be desired. In other words, portions of the dielectric frame 312 where the conductive layer 314 may be desired may not be covered by the stencil 332. In this aspect, only sub-frames 312b corresponding to the first contact pads may not be filled with the conductive layer 314. Conventional techniques may be employed, such as but not limited to, a dispense and printed process. In the top view of FIG. 3C, power bumps 322 and ground bumps 324 may be shown as dotted circles and may be described in later paragraphs.

FIG. 3D shows formation of a first underfill layer 318 in sub-frames 312b not filled with the conductive layer 314. Such sub-frames may align and correspond to the first contact pads 304 and/or signal bumps 320. Conventional techniques may be employed, such as but not limited to, a no-flow underfill (NUF) dispense process.

FIG. 3E shows attachment of a first device 310 onto the substrate 302. An adhesive layer 316 may be provided on the first device 310 for attachment to the dielectric frame 312. The first device 310 may include electrical connections, such as signal bumps 320, power bumps 322, and ground bumps 324, for electrical coupling to the substrate 302. In one aspect, signal bumps 320 may be provided in the sub-frames 312b corresponding to the first contact pads 304. In a further aspect, power bumps 322 may be provided in the power sub-frames 312b corresponding to the second contact pads 306. In another further aspect, ground bumps 324 may be provided in the sub-frames 312b corresponding to the third contact pads 308. Conventional techniques may be employed, such as but not limited to, solder reflow/thermal compression bonding process.

FIG. 3F shows attachment of solder balls 334 on the substrate 302 to complete the formation of the electronic assembly of FIG. 1A. Conventional techniques may be employed, such as but not limited to, solder reflow bonding process. Prior to this step, the carrier 330 may be removed or peeled off from the substrate 302. A second underfill layer 328 may be provided to encapsulate the dielectric frame 312, for example, by a jet dispense process.

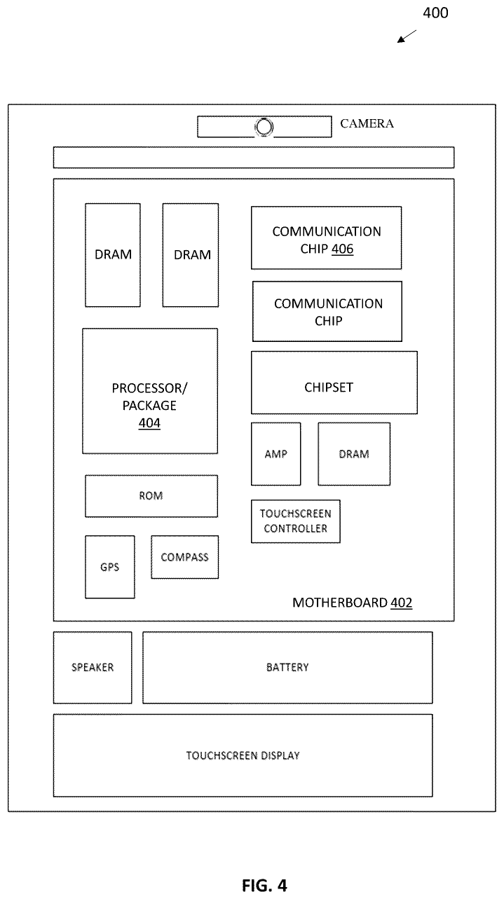

Aspects of the present disclosure may be implemented into a system using any suitable hardware and/or software. FIG. 4 schematically illustrates a computing device 400 that may include an electronic assembly as described herein, in accordance with some aspects. The computing device 400 may house a board such as a motherboard 402. The motherboard 402 may include a number of components, including but not limited to a processor 404 and at least one communication chip 406. The processor 404, which may have the electronic assembly according to the present disclosure, may be physically and electrically coupled to the motherboard 402. In some implementations, the at least one communication chip 406 may also be physically and electrically coupled to the motherboard 402. In further implementations, the communication chip 406 may be part of the processor or package 404.

Depending on its applications, computing device 400 may include other components that may or may not be physically and electrically coupled to the motherboard 402. These other components may include, but are not limited to, volatile memory (e.g. DRAM), non-volatile memory (e.g. ROM), flash memory, a graphics processor, a digital signal processor, a cryptoprocessor, a chipset, an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, a camera, and a mass storage device (such as hard disk drive, compact disk (CD), digital versatile disk (DVD), and so forth). In another aspect, the processor 404 of the computing device 400 may be packaged in an electronic assembly as described herein, and/or other semiconductor devices may be packaged together in an electronic assembly as described herein.

The communication chip 406 may enable wireless communications for the transfer of data to and from the computing device 400. The term “wireless” and its derivatives may be used to describe circuits, devices, systems, methods, techniques, communications channels, etc. that may communicate data through the use of modulated electromagnetic radiation through a non-solid medium. The term does not imply that the associated devices do not contain any wires, although in some aspects they might not. The communication chip 406 may implement any of a number of wireless standards or protocols, including but not limited to Institute for Electrical and Electronic Engineers (IEEE) standards including Wi-Fi (IEEE 502.11 family), IEEE 502.16 standards (e.g., IEEE 502.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 502.16 compatible BWA networks are generally referred to as WiMAX networks, an acronym that stands for Worldwide Interoperability for Microwave Access, which is a certification mark for products that pass conformity and interoperability tests for the IEEE 502.16 standards.

The communication chip 406 may also operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 406 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 406 may operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication chip 406 may operate in accordance with other wireless protocols in other aspects.

The computing device 400 may include a plurality of communication chips 406. For instance, a first communication chip 406 may be dedicated to shorter range wireless communications such as Wi-Fi and Bluetooth and a second communication chip 406 may be dedicated to longer range wireless communications such as GPS, EDGE, GPRS, CDMA, WiMAX, LTE, Ev-DO, and others.

In various implementations, the computing device 400 may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In an aspect, the computing device 400 may be a mobile computing device. In further implementations, the computing device 400 may be any other electronic device that processes data.

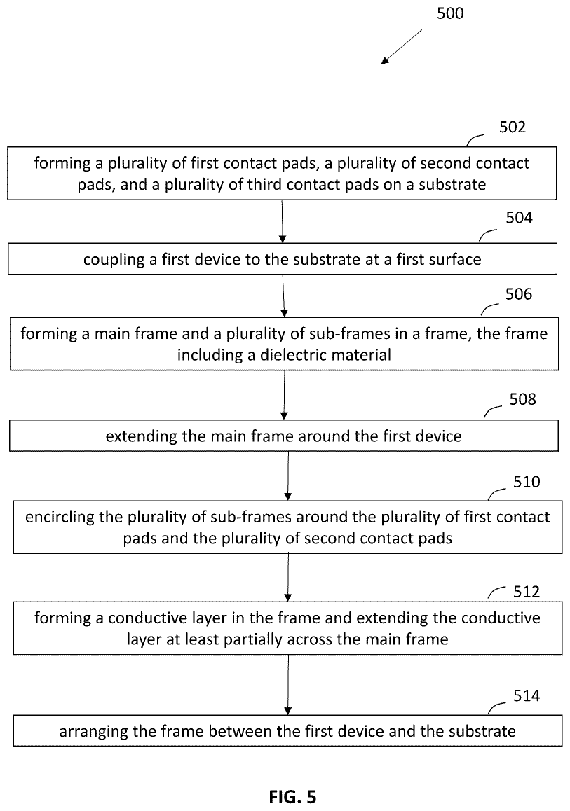

FIG. 5 shows a flow chart illustrating a method 500 of forming an electronic assembly according to an aspect of the present disclosure.

At operation 502, the method 500 may include forming a plurality of first contact pads, a plurality of second contact pads, and a plurality of third contact pads on a substrate.

At operation 504, the method 500 may also include coupling a first device to the substrate at a first surface.

At operation 506, the method 500 may include forming a main frame and a plurality of sub-frames in a frame. The frame may include a dielectric material.

At operation 508, the method 500 may further include extending the main frame around the first device.

At operation 510, the method 500 may also further include encircling the plurality of sub-frames around the plurality of first contact pads and the plurality of second contact pads.

At operation 512, the method 500 may also further include forming a conductive layer in the frame and extending the conductive layer at least partially across the main frame.

At operation 514, the method 500 may include arranging the frame between the first device and the substrate.

It will be understood that the above operations described above relating to FIG. 5 are not limited to this particular order. Any suitable, modified order of operations may be used.

### EXAMPLES

Example 1 may include an electronic assembly. The electronic assembly may include a substrate including a plurality of first contact pads, a plurality of second contact pads, and a plurality of third contact pads. The electronic assembly may include a first device including a first footprint coupled to the substrate at a first surface. The electronic assembly may include a frame arranged between the first device and the substrate, the frame including a dielectric material, the frame further including a main frame extending around the first device, and further including a plurality of sub-frames encircling the plurality of first contact pads and the plurality of second contact pads on the substrate, wherein the frame may further include a conductive layer extending at least partially across the main frame.

Example 2 may include the electronic assembly of example 1 and/or any other example disclosed herein, wherein the conductive layer may include a liquid metal selected from the group consisting of tin, indium, and gallium.

Example 3 may include the electronic assembly of example 1 and/or any other example disclosed herein, wherein the frame may include an organic mold compound layer, an epoxy polymer, a polyimide layer, or a silicone layer.

Example 4 may include the electronic assembly of example 1 and/or any other example disclosed herein, wherein the frame may be in contact with the first surface of the first device, the frame further including a second footprint greater than the first footprint of the first device.

Example 5 may include the electronic assembly of example 1 and/or any other example disclosed herein, wherein the frame may be coupled to the first surface of the first device through an adhesive layer.

Example 6 may include the electronic assembly of example 1 and/or any other example disclosed herein, wherein the first device further may include a plurality of interconnects extending from the first surface and coupled to the plurality of first contact pads, the plurality of second contact pads, and the plurality of third contact pads.

Example 7 may include the electronic assembly of example 6 and/or any other example disclosed herein, wherein the plurality of interconnects may further include a plurality of first interconnects and a plurality of second interconnects coupled to the plurality of first contact pads and the plurality of second contact pads respectively, wherein the plurality of first interconnects may be isolated from the plurality of second interconnects by a first portion of the conductive layer, and wherein the plurality of first interconnects may be configured to facilitate signal transmission and the plurality of second interconnects are configured to facilitate power delivery.

Example 8 may include the electronic assembly of example 7 and/or any other example disclosed herein, wherein two or more of the plurality of second interconnects are coupled to a second portion of the conductive layer and are encircled within the sub-frame of the frame to facilitate improved power delivery.

Example 9 may include the electronic assembly of example 6 and/or any other example disclosed herein, wherein the plurality of interconnects may further include a plurality of third interconnects coupled to the plurality of third contact pads, wherein the plurality of third interconnects may be associated with a ground reference voltage (Vss) to facilitate a current return path.

Example 10 may include the electronic assembly of example 9 and/or any other example disclosed herein, wherein the plurality of third interconnects may be coupled to the conductive layer.

Example 11 may include the electronic assembly of example 1 and/or any other example disclosed herein, wherein the substrate may include a silicon substrate, a multi-layer organic package, or a printed circuit board (PCB).

Example 12 may include the electronic assembly of example 1 and/or any other example disclosed herein, wherein the first device may include a central processing unit (CPU), a graphic processing unit (GPU), a system-on-chip (SOC), a memory device, a field programmable gate array (FGPA), an input/output (I/O) tile, or a combination thereof.

Example 13 may include a computing device. The computing device may include a circuit board and an electronic assembly coupled to the circuit board. The electronic assembly may include a substrate including a plurality of first contact pads, a plurality of second contact pads, and a plurality of third contact pads. The electronic assembly may include a first device including a first footprint coupled to the substrate at a first surface. The electronic assembly may include a frame arranged between the first device and the substrate, the frame including a dielectric material, the frame further including a main frame extending around the first device, and further including a plurality of sub-frames encircling the plurality of first contact pads and the plurality of second contact pads on the substrate, wherein the frame may further include a conductive layer extending at least partially across the main frame.

Example 14 may include the computing device of any one of examples 1 to 13 disclosed herein, wherein the conductive layer may include a liquid metal selected from the group consisting of tin, indium, and gallium.

Example 15 may include the computing device of any one of examples 1 to 14 disclosed herein, wherein the first device may further include a plurality of interconnects extending from the first surface and coupled to the plurality of first contact pads, the plurality of second contact pads, and the plurality of third contact pads.

Example 16 may include the computing device of any one of examples 1 to 15 disclosed herein, wherein the plurality of interconnects may further include a plurality of first interconnects and a plurality of second interconnects coupled to the plurality of first contact pads and the plurality of second contact pads respectively, wherein the plurality of first interconnects may be isolated from the plurality of second interconnects by a first portion of the conductive layer, and wherein the plurality of first interconnects may be configured to facilitate signal transmission and the plurality of second interconnects are configured to facilitate power delivery.

Example 17 may include the computing device of any one of examples 1 to 16 disclosed herein, wherein two or more of the plurality of second interconnects are coupled to a second portion of the conductive layer and are encircled within the sub-frame of the frame to facilitate improved power delivery.

Example 18 may include the computing device of any one of examples 1 to 17 disclosed herein, wherein the plurality of interconnects may further include a plurality of third interconnects coupled to the plurality of third contact pads, wherein the plurality of third interconnects may be associated with a ground reference voltage (Vss) to facilitate a current return path.

Example 19 may include a method. The method may include forming a plurality of first contact pads, a plurality of second contact pads, and a plurality of third contact pads on a substrate. The method may also include coupling a first device to the substrate at a first surface. The method may further include forming a main frame and a plurality of sub-frames in a frame, the frame including a dielectric material, extending the main frame around the first device and encircling the plurality of sub-frames around the plurality of first contact pads and the plurality of second contact pads. The method may include forming a conductive layer in the frame and extending the conductive layer at least partially across the main frame, and arranging the frame between the first device and the substrate.

Example 20 may include the method of example 19 and/or any other example disclosed herein, wherein forming the conductive layer in the frame may include forming a liquid metal selected from the group consisting of tin, indium, and gallium in the frame.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise” and “comprises”.

The term “coupled” (or “connected”) used herein may be understood as electrically coupled or as mechanically coupled, e.g., attached or fixed or mounted, or just in contact without any fixation, and it will be understood that both direct coupling and indirect coupling (in other words, coupling without direct contact) may be provided.

While the present disclosure has been particularly shown and described with reference to specific aspects, it should be understood by persons skilled in the art that various changes in form and detail may be made therein without departing from the scope of the present disclosure as defined by the appended claims. The scope of the present disclosure is thus indicated by the appended claims and all changes which come within the meaning and range of equivalency of the claims are therefore intended to be embraced.

What is claimed is:

1. An electronic assembly comprising:
a substrate comprising a plurality of first contact pads, a plurality of second contact pads, and a plurality of third contact pads;
a first device comprising a first footprint coupled to the substrate at a first surface; and
a frame arranged between the first device and the substrate, the frame comprising a dielectric material, the frame further comprising a main frame extending around the first device, and further comprising a plurality of sub-frames encircling the plurality of first contact pads and the plurality of second contact pads on the substrate,
wherein the frame further comprises a conductive layer extending at least partially across the main frame.

2. The electronic assembly of claim 1, wherein the conductive layer comprises a liquid metal selected from the group consisting of tin, indium, and gallium.

3. The electronic assembly of claim 1, wherein the frame comprises an organic mold compound layer, an epoxy polymer, a polyimide layer, or a silicone layer.

4. The electronic assembly of claim 1, wherein the frame is in contact with the first surface of the first device, the frame further comprising a second footprint greater than the first footprint of the first device.

5. The electronic assembly of claim 1, wherein the frame is coupled to the first surface of the first device through an adhesive layer.

6. The electronic assembly of claim 1, wherein the first device further comprises a plurality of interconnects extending from the first surface and coupled to the plurality of first contact pads, the plurality of second contact pads, and the plurality of third contact pads.

7. The electronic assembly of claim 6, wherein the plurality of interconnects further comprise a plurality of first interconnects and a plurality of second interconnects coupled to the plurality of first contact pads and the plurality of second contact pads respectively, wherein the plurality of first interconnects are isolated from the plurality of second interconnects by a first portion of the conductive layer, and wherein the plurality of first interconnects are configured to facilitate signal transmission and the plurality of second interconnects are configured to facilitate power delivery.

8. The electronic assembly of claim 7, wherein two or more of the plurality of second interconnects are coupled to a second portion of the conductive layer and are encircled within the sub-frame of the frame to facilitate improved power delivery.

9. The electronic assembly of claim 6, wherein the plurality of interconnects further comprise a plurality of third interconnects coupled to the plurality of third contact pads, wherein the plurality of third interconnects are associated with a ground reference voltage (Vss) to facilitate a current return path.

10. The electronic assembly of claim 9, wherein the plurality of third interconnects are coupled to the conductive layer.

11. The electronic assembly of claim 1, wherein the substrate comprises a silicon substrate, a multi-layer organic package, or a printed circuit board (PCB).

12. The electronic assembly of claim 1, wherein the first device comprises a central processing unit (CPU), a graphic processing unit (GPU), a system-on-chip (SOC), a memory device, a field programmable gate array (FGPA), an input/output (PO) tile, or a combination thereof.

13. A computing device comprising:
a circuit board; and
an electronic assembly coupled to the circuit board, the electronic assembly comprising:
a substrate comprising a plurality of first contact pads, a plurality of second contact pads, and a plurality of third contact pads;
a first device comprising a first footprint coupled to the substrate at a first surface; and
a frame arranged between the first device and the substrate, the frame comprising a dielectric material, the frame further comprising a main frame extending around the first device, and further comprising a plurality of sub-frames encircling the plurality of first contact pads and the plurality of second contact pads on the substrate,
wherein the frame further comprises a conductive layer extending at least partially across the main frame.

14. The computing device of claim 13, wherein the conductive layer comprises a liquid metal selected from the group consisting of tin, indium, and gallium.

15. The computing device of claim 13, wherein the first device further comprises a plurality of interconnects extending from the first surface and coupled to the plurality of first contact pads, the plurality of second contact pads, and the plurality of third contact pads.

16. The computing device of claim 15, wherein the plurality of interconnects further comprise a plurality of first interconnects and a plurality of second interconnects coupled to the plurality of first contact pads and the plurality of second contact pads respectively, wherein the plurality of first interconnects are isolated from the plurality of second interconnects by a first portion of the conductive layer, and wherein the plurality of first interconnects are configured to facilitate signal transmission and the plurality of second interconnects are configured to facilitate power delivery.

17. The computing device of claim 16, wherein two or more of the plurality of second interconnects are coupled to a second portion of the conductive layer and are encircled within the sub-frame of the frame to facilitate improved power delivery.

18. The computing device of claim 15, wherein the plurality of interconnects further comprise a plurality of third interconnects coupled to the plurality of third contact pads, wherein the plurality of third interconnects are associated with a ground reference voltage (Vss) to facilitate a current return path.

19. A method comprising:
forming a plurality of first contact pads, a plurality of second contact pads, and a plurality of third contact pads on a substrate;
coupling a first device to the substrate at a first surface;
forming a main frame and a plurality of sub-frames in a frame, the frame comprising a dielectric material;
extending the main frame around the first device;
encircling the plurality of sub-frames around the plurality of first contact pads and the plurality of second contact pads;
forming a conductive layer in the frame and extending the conductive layer at least partially across the main frame; and
arranging the frame between the first device and the substrate.

20. The method of claim 19, wherein forming the conductive layer in the frame comprises forming a liquid metal selected from the group consisting of tin, indium, and gallium in the frame.
